(19) United States
(12) Patent Application Publication
(10) Pub. No.: US 2025/0343442 A1
(43) Pub. Date: Nov. 6, 2025

(54) SYSTEMS AND METHODS FOR DETERMINING MUTUAL INDUCTANCE IN A WIRELESS INDUCTIVE POWER TRANSFER SYSTEM BEFORE CHARGING

(71) Applicant: AcLeap Power Inc., Taipei City (TW)

(72) Inventors: Lishen ZHOU, Shanghai City (CN); Junfeng GUAN, Shanghai City (CN); Qin SUN, Shanghai City (CN); Juan ZHANG, Shanghai City (CN)

(21) Appl. No.: 19/196,104

(22) Filed: May 1, 2025

(30) Foreign Application Priority Data
May 6, 2024 (WO) PCT/CN2024/091204

(51) Int. Cl. H02J 50/12; G01R 27/26; H02J 7/00

(52) U.S. Cl. CPC H02J 50/12; G01R 27/2611; H02J 7/0047; H02J 7/00712; H02J 2207/20

(57) ABSTRACT

A wireless inductive power transfer (IPT) system for wirelessly charging electrical equipment is provided. The system includes a transmitter resonant circuit configured to transmit a primary alternating current (AC) power. The system also includes a receiver resonant circuit inductively coupled with the transmitter resonant circuit and configured to receive the primary AC power and output a secondary AC power. The system further includes a mutual inductance measurement circuitry configured to measure a mutual inductance between the transmitter resonant circuit and the receiver resonant circuit before initiating charging of electrical equipment by operating the IPT system such that the secondary AC current is zero at an operating frequency of the IPT system, measuring the secondary AC voltage and the primary AC current, determining the mutual inductance based on the secondary AC voltage and the primary AC current, and outputting the determined mutual inductance.

### CROSS-REFERENCE TO RELATED APPLICATIONS

This application claims priority to International Patent Application No. PCT/CN2024/091204, filed May 6, 2024 and titled “SYSTEMS AND METHODS FOR DETERMINING MUTUAL INDUCTANCE IN A WIRELESS INDUCTIVE POWER TRANSFER SYSTEM BEFORE CHARGING”, the entire contents of which are hereby incorporated by reference.

### BACKGROUND

The field of the disclosure relates generally to power transfer, and more particularly, to systems and methods for wireless power transfer for electrical equipment.

A wireless inductive power transfer (IPT) system is used in wirelessly charging an electric vehicle. The power transfer system includes a transmitter and a receiver magnetically coupled with one another. Mutual inductance indicates the strength of coupling between the transmitter and the receiver. Measuring mutual inductance before charging is desirable for the control and operation of the transfer system. Most known IPT systems, however, do not measure the mutual inductance before charging. Known methods and assemblies for measuring mutual inductance before charging are disadvantaged in some aspects and improvements are desired.

### BRIEF DESCRIPTION

In one aspect, a wireless inductive power transfer (IPT) system for wirelessly charging electrical equipment is provided. The system includes a transmitter resonant circuit configured to transmit a primary alternating current (AC) power, the primary AC power having a primary AC current. The system also includes a receiver resonant circuit inductively coupled with the transmitter resonant circuit and configured to receive the primary AC power and output a secondary AC power, the secondary AC power having a secondary AC voltage and a secondary AC current. The system further includes a mutual inductance measurement circuitry configured to measure a mutual inductance between the transmitter resonant circuit and the receiver resonant circuit before initiating charging of electrical equipment by operating the IPT system such that the secondary AC current is zero at an operating frequency of the IPT system, measuring the secondary AC voltage and the primary AC current, determining the mutual inductance based on the secondary AC voltage and the primary AC current, and outputting the determined mutual inductance.

In another aspect, a mutual inductance measurement circuitry for measuring a mutual inductance in a wireless IPT system before initiating charging of electrical equipment by the IPT system is provided. The IPT system includes a transmitter resonant circuit and a receiver resonant circuit inductively coupled with the transmitter resonant circuit. The transmitter resonant circuit is configured to transmit a primary AC power having a primary AC current. The receiver resonant circuit is configured to receive the primary AC power and output a secondary AC power, the secondary AC power having a secondary AC voltage and a secondary AC current. The mutual inductance measurement circuitry is configured to operate the IPT system such that the secondary AC current is zero at an operating frequency of the IPT system, measure the secondary AC voltage and the primary AC current, determine the mutual inductance based on the secondary AC voltage and the primary AC current, and output the determined mutual inductance.

In one more aspect, a method of operating a wireless IPT system for wirelessly charging electrical equipment is provided. The IPT system includes a transmitter resonant circuit and a receiver resonant circuit inductively coupled with the transmitter resonant circuit. The transmitter resonant circuit is configured to transmit a primary AC power having a primary AC current. The receiver resonant circuit is configured to receive the primary AC power and output a secondary AC power, the secondary AC power having a secondary AC voltage and a secondary AC current. The method includes before initiating charging of electrical equipment by the IPT system, operating the IPT system such that the secondary AC current is zero at an operating frequency of the IPT system, measuring the secondary AC voltage and the primary AC current, determining mutual inductance between the transmitter resonant circuit and the receiver resonant circuit based on the secondary AC voltage and the primary AC current, and outputting the determined mutual inductance.

### BRIEF DESCRIPTION OF DRAWINGS

These and other features, aspects, and advantages of the present disclosure will become better understood when the following detailed description is read with reference to the accompanying drawings in which like characters represent like parts throughout the drawings.

FIG. 1A is a schematic diagram of an example wireless inductive power transfer (IPT) system.

FIG. 1B is a high-level circuit diagram of the system shown in FIG. 1A.

FIG. 1C is a schematic diagram of an example embodiment of the system shown in FIG. 1A.

FIG. 1D is a flow chart of an example method of operating an IPT system as disclosed herein.

FIG. 2 is a high-level circuit diagram of an example embodiment of the system shown in FIG. 1B.

FIG. 3A is a circuit diagram for measuring mutual inductance using the method shown in FIG. 1D.

FIG. 3B shows example waveforms of measured secondary AC voltage and primary AC current, using the circuit shown in FIG. 3A, where mutual inductance is determined based on the secondary AC voltage and the primary AC current.

FIG. 3C is a circuit diagram of an example mechanism in sensing the secondary AC voltage in deriving the waveform for the secondary AC voltage shown in FIG. 3B.

FIG. 4A shows parasitic capacitance in the circuit shown in FIG. 3A.

FIG. 4B shows the effects of the parasitic capacitance illustrated in FIG. 4A on measuring the secondary AC voltage.

### DETAILED DESCRIPTION

The disclosure includes inductive power transfer (IPT) systems, and methods of operating the IPT systems including methods for determining mutual inductance in a wireless IPT system before charging a vehicle. An automated guide vehicle (AGV) is used as an example. The systems and methods described herein may be applied to an electric vehicle in general. An electric vehicle is a vehicle that operates on an electric motor, and may be a battery electric vehicle (BEV), a plug-in hybrid electric vehicle (PHEV), or a hybrid electric vehicle (HEV). The systems and methods described herein may be applied to electrical equipment in general, such as any equipment at least partially powered by electricity, especially for electrical equipment in locations inaccessible to electrical connection with a charger, such as underwater, explosive, and/or flammable environments. Method aspects will be in part apparent and in part explicitly discussed in the following description.

An IPT system for charging a battery is advantageous over conventional plug-in charging systems, such as elimination of charger connecters and user convenience. An IPT system may be used to charge an electric vehicle.

An IPT system is based on magnetic coupling between two coils of a relatively very high frequency transformer. The first coil of the transformer is mounted on the charger side. The second coil is installed on the vehicle. Typically, single-phase or three-phase AC power supply of frequency 50-60 Hz is first rectified to DC, and then the rectified DC is inverted to very high frequency AC in the charger. The very-high frequency power is transferred to the battery through magnetically coupled primary and secondary coils. The high-frequency AC power received through the vehicle side coil is converted to DC to charge the battery on the vehicle, transferring electrical energy from a transmitter side to a receiver side using a magnetic field.

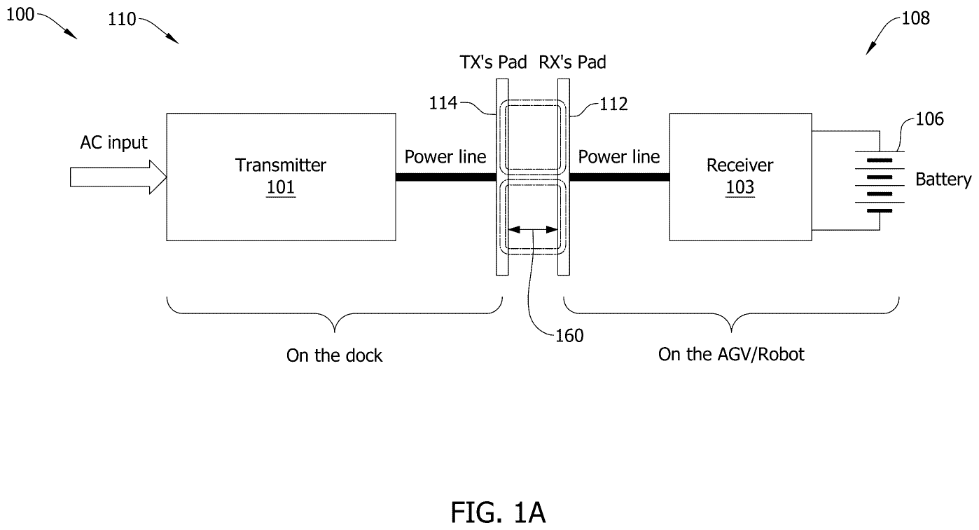

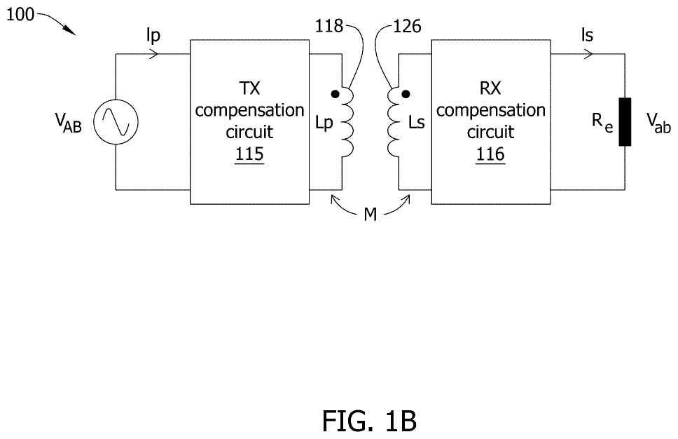

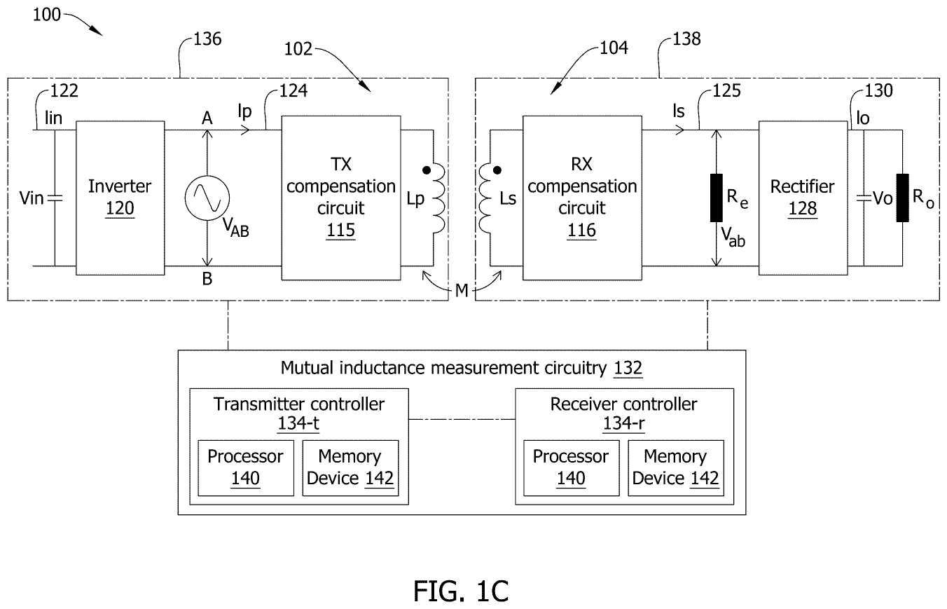

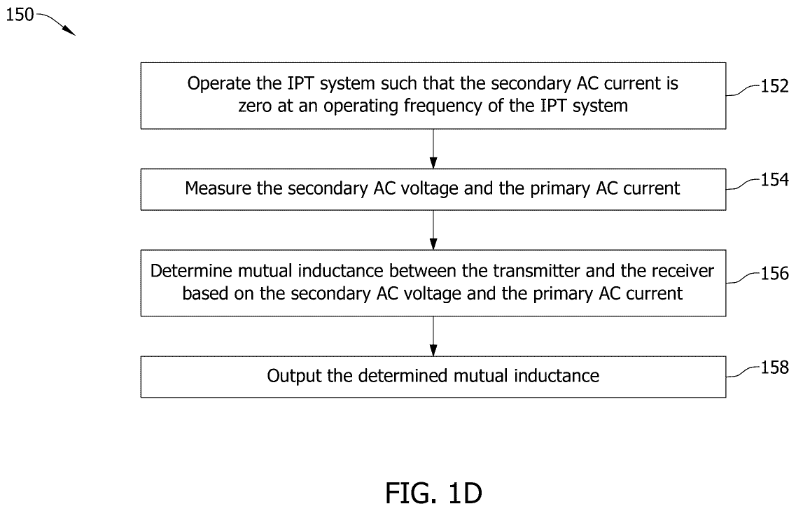

FIGS. 1A-1D show an example wireless IPT system 100 (FIGS. 1A-1C) and an example method 150 of measuring mutual inductance M in the system 100 before charging a vehicle using the IPT system 100 (FIG. 1D). FIG. 1A is a schematic diagram of the system 100. FIG. 1B is a high-level circuit diagram of the system 100 shown in FIG. 1A. FIG. 1C is a high-level circuit diagram of an example embodiment of the system 100 shown in FIG. 1A.

In the example embodiment, the system 100 includes a transmitter-side subsystem 136 at the transmitter side, which includes a transmitter 101. The transmitter side may be referred to as the primary side. The transmitter-side subsystem 136 is configured to receive electrical power from a power source. The system 100 further includes a receiver-side subsystem 138 at the receiver side, which includes a receiver 103. The receiver side may be referred to as the secondary side. The receiver 103 is inductively coupled with the transmitter 101. The receiver-side subsystem 138 is configured to output electrical power to a battery 106 to charge the battery 106.

In operation, an AGV 108 is driven to the dock of a charging station 110. A receiver pad 112 of the AGV is placed adjacent to a transmitter pad 114 of the charging station. The transmitter 101 is loosely, inductively coupled with the receiver 103 and power is transmitted by the transmitter 101 to the receiver 103 to charge the battery 106 of the AGV. In some embodiments, the transmitter pad 114 and the transmitter 101 are formed as one single unit, and/or the receiver pad 112 and the receiver 103 are formed as one single unit.

Because of the loose coupling between the transmitter 101 and the receiver 103, compensation circuits 115, 116 may be included in the primary side (or the transmitter side) and the secondary side (or the receiver side) (see FIG. 1B). The compensation circuits 115, 116 may be series-series, series-parallel, parallel-series, or parallel-parallel, where the compensation circuit 116 may be electrically connected with the transformer circuit in series or in parallel on the primary side or the secondary side. For example, if the compensation circuit is series-series, the compensation circuit on the primary side is electrically connected with the transmitter coil 118 in series and the compensation circuit on the secondary side is electrically connected with the receiver coil 126 in series. The compensation circuits 115, 116 may be in composite topologies, such as LC-S, LCC-S, LC-LC, or LCC-LCC.

Referring to FIG. 1C, a high-level circuit diagram of an example embodiment of the system 100, the system 100 includes the transmitter-side subsystem 136 and the receiver-side subsystem 138. The transmitter-side subsystem 136 includes the transmitter resonant circuit 102. The transmitter resonant circuit 102 includes the transmitter coil 118. The transmitter resonant circuit 102 may further include the transmitter compensation circuit 115 to increase the efficiency of power transfer in the system 100. The transmitter-side subsystem 136 further includes an inverter 120 configured to convert a DC power to an AC power at a relatively high frequency, such as in the range of kilohertz or greater. The AC power 124 output from the inverter 120 or the input power to the transmitter resonant circuit 102 may be referred to as a primary AC power. The primary AC power has a voltage V_{AB}, and a primary AC current Ip. Voltage V_{AB} may be referred to as a primary AC voltage V_{AB}. Current Ip may be referred to as a primary AC current Ip. The DC power 122 input to the inverter 120 may be referred to as an input DC power 122 to the system 100. The input DC power 122 has a voltage Vin and a current Iin. The system 100 may receive power from a DC power supply. Alternatively, the system 100 receives AC power from power utility, where the AC power is converted to the input DC power 122 via an AC/DC converter. In some embodiments, a DC/DC converter (not shown) may be used to change the voltage of the DC power output from the AC/DC converter to the voltage of the input DC power 122 to the inverter 120.

In the example embodiments, the receiver-side subsystem 138 incudes the receiver resonant circuit 104. The receiver resonant circuit 104 includes the receiver coil 126. The transmitter coil 118 and the receiver coil 126 are magnetically coupled with one another to facilitate power transfer. The receiver resonant circuit 104 may further include the receiver compensation circuit 116 to increase the efficiency in power transfer. The receiver-side subsystem 138 further includes a rectifier 128 configured to convert the AC power output from the receiver resonant circuit 104 into a DC output power 130. The DC output power 130 is transmitted to the battery 106 of the vehicle 108 for charging the vehicle 108. Ro denotes the output equivalent resistance of the battery 106, which is the voltage Vo across the battery 106 divided by the output DC current Io. Vo denotes the DC output voltage. Re denotes the equivalent impedance to the secondary AC power 125. The secondary AC power 125 has a voltage V_{ab} and a current Is. The voltage V_{ab} may be referred to as the secondary AC voltage V_{ab}. The current Is may be referred to as the secondary AC current Is.

In the example embodiment, the system 100 further includes a mutual inductance measurement circuitry 132 configured to measure the mutual inductance M before charging. Mutual inductance M is related to the gain or transconductance in the system 100, therefore being a key parameter of the IPT system. The mutual inductance measurement circuitry 132 includes controllers 134. At least part of the mutual inductance measurement circuitry 132 is implemented on the controllers 134. The mutual inductance measurement circuitry 132 may further include sensors (not show) for sensing voltage and/or current. The mutual inductance measurement circuitry 132 may further include other components, such as circuitry for sensing electrical parameters or operating the IPT system, that enable the system 100 to function as described herein.

In the example embodiment, the system 100 may further include a transmitter controller 134-t. The transmitter controller 134-t may be included in the charging station 110. The transmitter controller 134-t is in communication with the transmitter-side subsystem 136 via wire or wireless communication mechanisms. The transmitter controller 134-t may be incorporated with the transmitter-side subsystem 136 or positioned separately from the transmitter-side subsystem 136. The transmitter controller 134-t provides control of the transmitter-side subsystem 136, such as controlling the switching of the switches in the inverter 120.

In the example embodiment, the system 100 further includes a receiver controller 134-r. The receiver controller 134-r may be positioned in the vehicle 108. The receiver controller 134-r communicates with the receiver-side subsystem 138 via wired or wireless communication mechanisms. The receiver controller 134-r may be incorporated with the receiver-side subsystem 138 or positioned separately from the receiver-side subsystem 138. The receiver controller 134-r is configured to control the operation of the receiver-side subsystem 138, such as controlling the switching of the switches in the rectifier 128.

In the example embodiment, the transmitter controller 134-t communicates with the receiver controller 134-r. In some embodiments, instead of a transmitter controller 134-t and a receiver controller 134-r, the system 100 includes a master controller (not shown), which communicates with the transmitter-side subsystem 136 and the receiver-side subsystem 138 wirelessly, or via wired communication with one of the subsystems 136, 138 and via wireless communication with the other subsystem 136, 138.

In the example embodiment, the controller 134 includes a processor-based microcontroller including a processor 140 and a memory device 142 wherein executable instructions, commands, and control algorithms, as well as data and information needed to satisfactorily operate the controller 134, are stored. The memory device 142 may be, for example, a random-access memory (RAM), and other forms of memory used in conjunction with RAM memory, including but not limited to flash memory (FLASH), programmable read only memory (PROM), and electronically erasable programmable read only memory (EEPROM).

As used herein, the term “processor-based” microcontroller shall refer not only to controller devices including a processor or microprocessor as shown, but also to other equivalent elements such as microcomputers, programmable logic controllers, reduced instruction set circuits (RISC), application specific integrated circuits (ASIC), field programmable gate array (FPGA), and other programmable circuits, logic circuits, equivalents thereof, and any other circuit or processor capable of executing the functions described below. The processor-based devices listed above are examples only, and are thus not intended to limit in any way the definition and/or meaning of the term “processor-based.”

In operation, the input DC power (Vin, Iin) is converted by the inverter 120 into the primary AC power 124 (V_{AB}, Ip). The primary AC power 124 is transmitted by the transmitter resonant circuit 102 and received by the receiver resonant circuit 104. The receiver resonant circuit 104 outputs the secondary AC power (V_{ab}, Is). The secondary AC power is rectified into the DC output power 130 and transmitted to the battery 106 of the vehicle 108 for charging.

To charge a vehicle 108, the vehicle 108 moves to the charging station 110 and the receiver pad 112 of the vehicle 108 is placed adjacent to the transmitter pad 114. The vehicle 108 establishes communication with the charging station 110 via the controllers 134. Before charging is initiated, the mutual inductance measurement circuitry 132 determines the mutual inductance M between the transmitter resonant circuit 102 and the receiver resonant circuit 104. The control and operation parameters, such as input power, may be adjusted based on the measured mutual inductance M. In some embodiments, charging is initiated only when the measured mutual inductance M is within a predefined range. If the measured mutual inductance M is outside the predefined range, the system 100 may alert the vehicle and/or provide instructions for the vehicle to move or adjust positioning of the receiver pad 112 such that the mutual inductance M of the new configuration is within the predefined range.

FIG. 1D is a flow chart of an example method 150 for operating the system 100. In the example embodiment, the method 150 includes operating 152 the IPT system such that the secondary AC current is zero at an operating frequency of the IPT system. The method 150 also includes measuring 154 the secondary AC voltage and the primary AC current. The method 150 further includes determining 156 mutual inductance between the transmitter and the receiver based on the secondary AC voltage and the primary AC current. In addition, the method 150 includes outputting 158 the determined mutual inductance. Operating 152, measuring 154, determining 156, and outputting 158 are performed before initiating the charging of the vehicle. The method 150 may be implemented on the mutual inductance measurement circuitry 132.

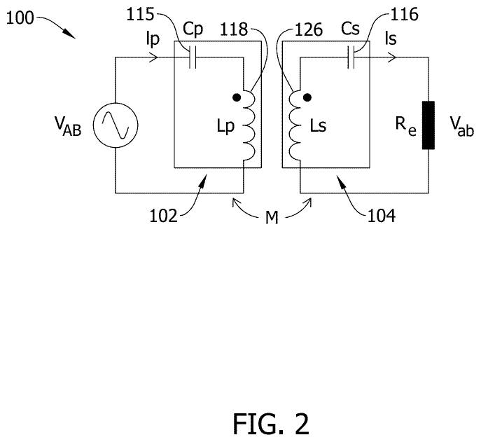

FIG. 2 is a high-level circuit diagram of an example embodiment of the system 100. In the example embodiment, the compensation circuits 115, 116 are series-series. The transmitter compensation circuit 115 includes a primary compensation capacitor Cp electrically connected in series with the transmitter coil 118. The receiver compensation circuit 116 includes a secondary compensation capacitor Cs electrically connected in series with the receiver coil 126. The transmitter coil 118 and the receiver coil 126 are magnetically coupled with one another. Mutual inductance M indicates the strength of magnetic coupling between the transmitter coil 118 and the receiver coil 126. A higher M indicates a stronger coupling, and vice versa. The gap 160 (see FIG. 1A), the distance between the pads 112, 114, affects the mutual inductance M. A smaller gap 160 will have a higher mutual inductance M, and a bigger gap 160 will have a lower mutual inductance M.

In an IPT system, the relative positioning between the transmitter and the receiver always changes because different vehicles have different positioning of the pad and even the same vehicle may park differently and have different positioning during different charging sessions. Therefore, the mutual inductance M for each charging session is different, and is desirable to be measured before initiation of the charging session for the control and protection of the system.

Mutual inductance M is related to the transconductance between the primary AC power (V_{AB}, Ip) and the secondary AC power (V_{ab}, Is), as below:

$${V}_{AB} = {I}_{p} \cdot \frac{1}{j ω {C}_{p}} + {I}_{p} \cdot j ω {L}_{p} - \text{?} \cdot j ω M , \qquad ( 1 )$$

$${V}_{ab} = - \text{?} \cdot \frac{1}{j ω \text{?}} - \text{?} \cdot j ω \text{?} + {I}_{p} \cdot j ω M . \qquad ( 2 )$$

$$\text{?} \text{indicates text missing or illegible when filed}$$

ω is the angular operating frequency of the system 100, and is the angular switching frequency of the switches in the inverter 120. The switching frequency of the switches in the rectifier 128 may be the same as the switching frequency of the switches in the inverter 120. For simplicity of discussion to show the relationship of the primary AC voltage V_{AB} and/or primary AC current Ip with the secondary AC voltage V_{ab} and/or the secondary AC current Is, a special instance is provided below. In the special instance, the resonant frequency of the primary side or the transmitter resonant circuit 102 is the same as the resonant frequency of the secondary side or the receiver resonant circuit 104, and is the same as the operating frequency ω.

When

$${ω}_{0} = \frac{1}{\sqrt{\text{?}}} = \frac{1}{\sqrt{\text{?}}} \qquad ( 3 )$$

$${V}_{AB} = - \text{?} \cdot j {ω}_{0} M$$

$${I}_{p} = \frac{{V}_{ab}}{j {ω}_{0} M}$$

$$or$$

$$\text{?} = \frac{{V}_{AB}}{- j {ω}_{0} M} ,$$

$$\text{?} \qquad ( 4 )$$

$$\text{?} \text{indicates text missing or illegible when filed}$$

In charging a vehicle with an IPT system, a constant current (CC) mode or a constant voltage (CV) mode is used. In the CC mode, the output current Io is kept constant, while the output voltage Vₒ increases. In the CV mode, the output voltage Vo is kept constant, while the output current Io reduces. A charging session typically starts with a CC portion, where the charging is in the CC mode, and follows with a CV portion, where the charging is in the CV mode. In the CV portion, the output DC current Io being equal to or less than a predefined value indicates that the battery is fully charged.

As shown in Eqn. (3), for the charging to be in a CC mode, when the mutual inductance M increases, the primary AC voltage V_{AB} needs to be increased, and when the mutual inductance M reduces, the primary AC voltage V_{AB} needs to be decreased. The mutual inductance M demands the primary AC voltage V_{AB} or the primary AC current Ip to be at a certain level during charging. Therefore, in order for the system 100 to function properly, the mutual inductance M should be within a predefined range. For example, if the mutual inductance M is too high, the required primary AC voltage V_{AB} may become too high and exceed the limit of the system 100. If the mutual inductance M is too low, the required primary AC current Ip may become too high and exceed the limit of the system 100 if the input power remains the same. The predefined range of the mutual inductance M may be determined based on the range of the gap 160, the operating frequency of the system 100, the system limit on the primary AC voltage V_{AB}, and/or the system limit on the primary AC current Ip. The range of the gap 160 may be provided by a user of the system 100. An example range of the gap 160 is 30 mm to 50 mm. The decrease in the gap 160 typically increases mutual inductance M, and vice versa.

Determining the mutual inductance M before initiating a charging session is advantageous in controlling and protecting the system 100. For example, input power may be adjusted such that the primary AC voltage or the primary AC current meets the required primary AC voltage or the primary AC current demanded by the mutual inductance M. Overvoltage protection measures and/or over current protection measures may be implemented when the measured mutual inductance M indicates the required voltage or current will be over a desired range. The rotation speed of one or more cooling fans in the system 100 may be adjusted based on the required primary AC current Ip. In some embodiments, the charging session is initiated only when the measured mutual inductance M is within the predefined range to protect the system 100.

Referring back to Eqns. (1) and (2), if Is is equal to zero at an operating frequency of the IPT system 100, Eqns. (1) and (2) becomes:

$${V}_{AB} = {I}_{p} \cdot \frac{1}{j ω {C}_{p}} + {I}_{p} \cdot j ω {L}_{p} or \qquad ( 5 )$$

$${I}_{p} = \frac{{V}_{AB}}{\frac{1}{\text{?}} + \text{?}} \text{?}$$

$${V}_{ab} = {I}_{p} \cdot j ω M . \qquad ( 6 )$$

$$\text{?} \text{indicates text missing or illegible when filed}$$

Based on Eqn. (6), the mutual inductance M may be measured based on the secondary AC voltage V_{ab} and the primary AC current Ip as:

$$M = \frac{{V}_{ab}}{\text{?}} . \qquad ( 7 )$$

$$\text{?} \text{indicates text missing or illegible when filed}$$

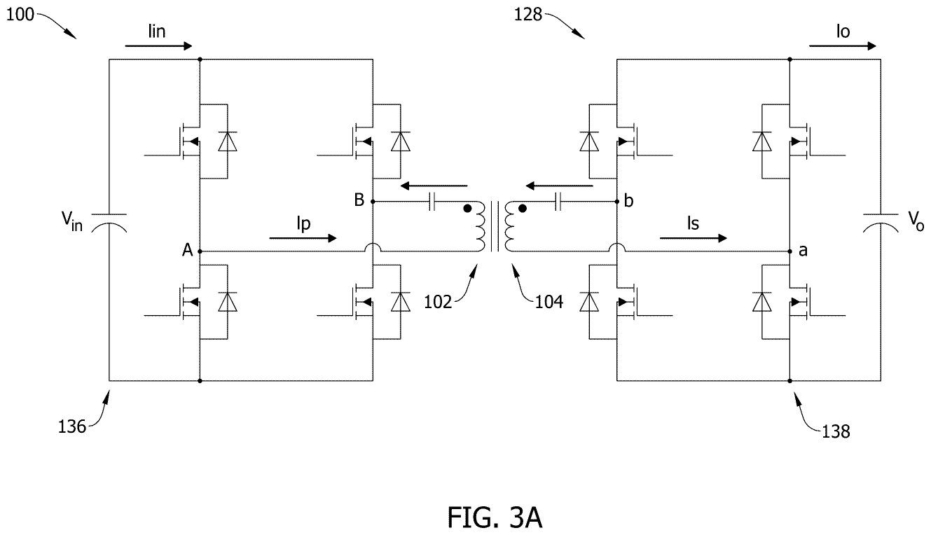

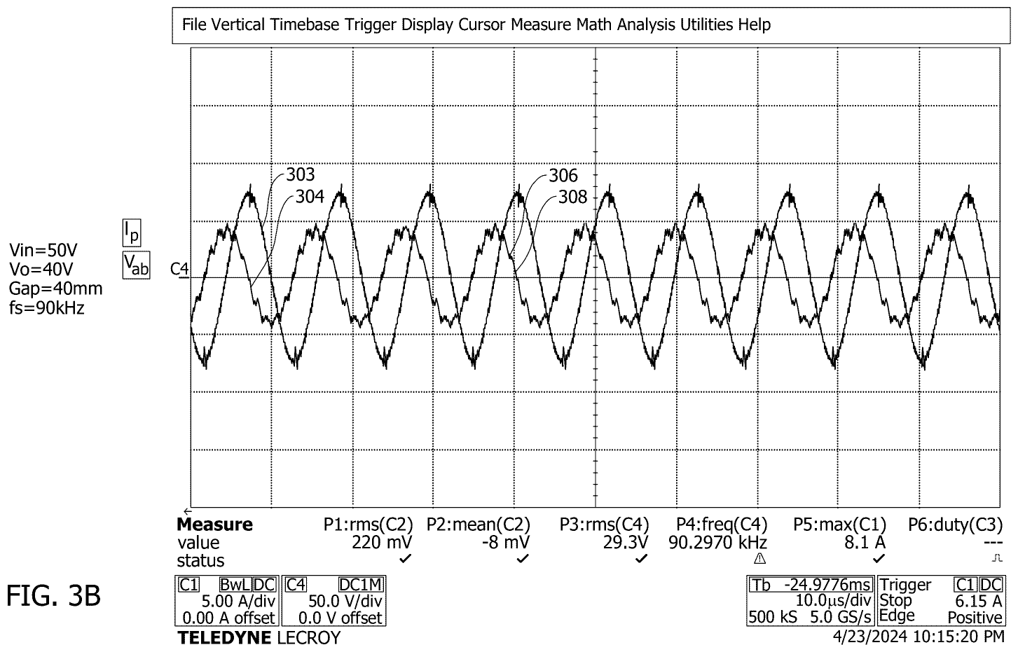

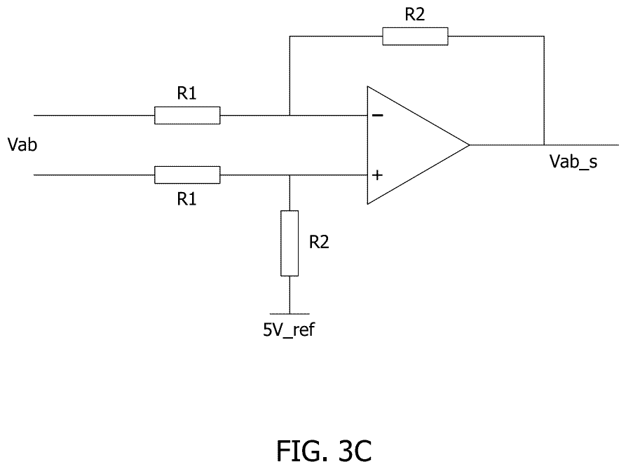

FIG. 3A is a circuit diagram of an example circuit for measuring the mutual inductance M. In the example embodiment, after IPT system 100 is ready but before charging, the output voltage Vo is clamped to a clamping voltage. The clamping voltage may be selected as approximately the same as the voltage of the battery 106. The transmitter-side subsystem 136 supplies an input DC power having an input DC voltage Vin such that the secondary AC voltage V_{ab} is lower than the clamping voltage Vo, and the rectifier 128 does not conduct. As a result, the secondary AC current Is is zero at the operating frequency. If the secondary AC voltage V_{ab} is greater than the clamping voltage Vo, the rectifier 128 will conduct and the secondary AC current Is is not zero. The secondary AC voltage V_{ab} will be clamped to the clamping voltage Vo, instead of changing as a function of the mutual inductance M, preventing measurement of the mutual inductance M based on the secondary AC power V_{ab} and the primary AC current Ip, as shown in Eqn. (7).

In some embodiments, the operating frequency fs

$$( {f}_{s} = \frac{ω}{2 π} )$$

of the system 100 is selected to be different from the resonant frequency of the transmitter resonant circuit 102. Referring back to Eqn. (5), if the operating frequency fs is the same as the resonant frequency of the transmitter resonant circuit 102, the primary AC current Ip may become very large as the impedance of the system 100 becomes very small. The circuit of the system 100 may be configured to adjust the resonant frequency of the transmitter resonant circuit 102. For example, the capacitance and/or inductance of the transmitter resonant circuit 102 may be adjusted to change the resonant frequency of the transmitter resonant circuit 102.

In other embodiments, in operating the system 100, zero voltage switching is desirable for improving the efficiency of power transfer in the system 100. Zero voltage switching may be achieved by configuring the system 100 such that the operating frequency is higher than the resonant frequency of the transmitter resonant circuit 102.

In the example embodiment, both the primary AC current Ip and the secondary AC voltage V_{ab} are sinusoidal waves. Because the root mean square value of a sinusoidal wave is proportional to the mean value or the peak value of the sinusoidal wave, the mutual inductance M may be measured using the mean value or the peak value of the primary AC current Ip and the secondary AC voltage V_{ab} as:

$$M = \frac{\overline{\vert {V}_{ab} \vert}}{2 π \text{?}} or \qquad ( 8 )$$

$$M = \frac{\text{?}}{2 π \text{?}} . \qquad ( 9 )$$

$$\text{?} \text{indicates text missing or illegible when filed}$$

Because for an AC current and an AC voltage, the peak value is related to the mean value with a set coefficient, the mutual inductance M may be determined by a peak value or a mean value of the primary AC current Ip and a peak value or a mean value of the secondary AC voltage V_{ab}.

In a known method, to measure the mutual inductance before charging of the vehicle, the system needs to meet and operate at a stringent condition that the resonant frequency of the transmitter resonant circuit is the same as the resonant frequency of the receiver resonant circuit and the operating frequency of the system is forced to be the same as the resonant frequency. The condition is difficult to meet because of tolerance of components in the system, the differences in vehicles, and changes in positioning of even the same vehicle. In the known method, assuming the stringent condition is met, the mutual inductance is measured as being proportional to the ratio between the primary AC voltage V_{AB} and the secondary AC current Is, where the primary AC voltage V_{AB} is set as a square wave. Because the secondary AC current Is is a sinusoidal wave, first harmonic approximation is used to approximate the primary AC voltage V_{AB} in order to determining the ratio between the primary AC voltage V_{AB} and the secondary AC current Is. As a result, the accuracy of the measured mutual inductance in the known method is suboptimal.

In contrast, unlike most known methods, which measure the mutual inductance only during charging, the systems and methods described herein advantageously provide measuring of mutual inductance before charging the vehicle. Compared to the known method for measuring mutual inductance before charging, the systems and methods described herein are advantageous in providing flexible system configuration and accurate measurement of mutual inductance. The resonant frequency of the transmitter resonant circuit is not required to be the same as the resonant frequency of the receiver resonant circuit, or the operating frequency of the system is not required to be the same as either resonant frequency. The operating frequency and the resonant frequencies may be selected or configured for improved efficiency of the system during charging. Further, because mutual inductance is based on a ratio between the secondary AC voltage V_{ab} and the primary AC current Ip, both of which may be sinusoidal waves, an approximation is not needed in determining mutual inductance, thereby increasing the accuracy in measuring mutual inductance.

FIG. 3B shows example waveforms of measured primary AC current Ip (waveform 303) and measured secondary AC voltage V_{ab} (waveform 304). The input DC voltage Vin is selected as 50 V, the clamping voltage Vo is set as 40 V, the gap 160 between the pads 112, 114 is selected as 40 mm, and the switching frequency fₛ is selected as 90 kHz.

FIG. 3C is an example circuit diagram in sensing the secondary AC voltage V_{ab}. In the example embodiment, the secondary AC voltage V_{ab} is sensed by differential sampling, such that the waveform 304 of the measured secondary AC voltage V_{ab} is centered around zero in the y-axis of the plot (see FIG. 3B).

Referring back to FIG. 3B, compared to the waveform 303 of the primary AC current Ip, the waveform 304 of the secondary AC voltage V_{ab} has a high-frequency oscillation 306 overlaid on the base frequency component 308. The base frequency component 308 may be in the range of kilohertz, while the high-frequency oscillation 306 may be in the range of megahertz. The high-frequency oscillation 306 stems from parasitic capacitors of the rectifier 128.

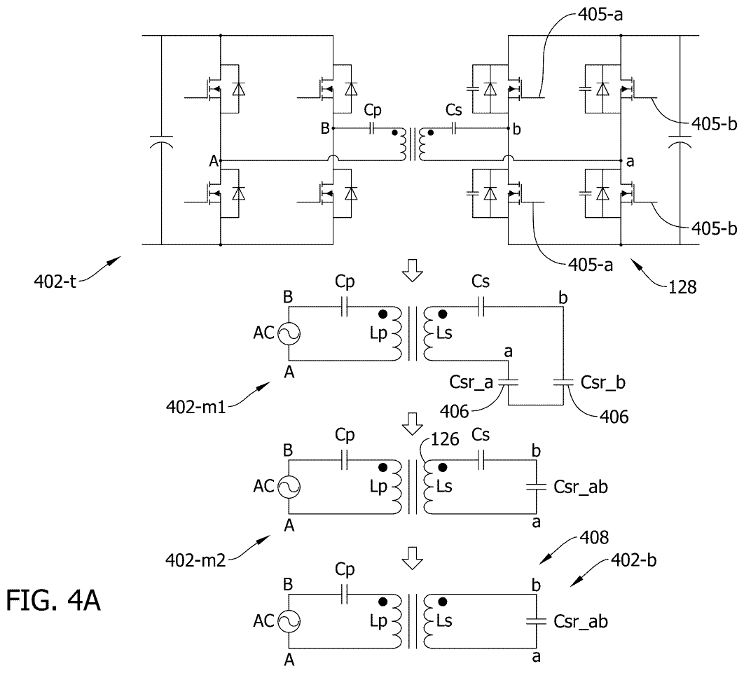

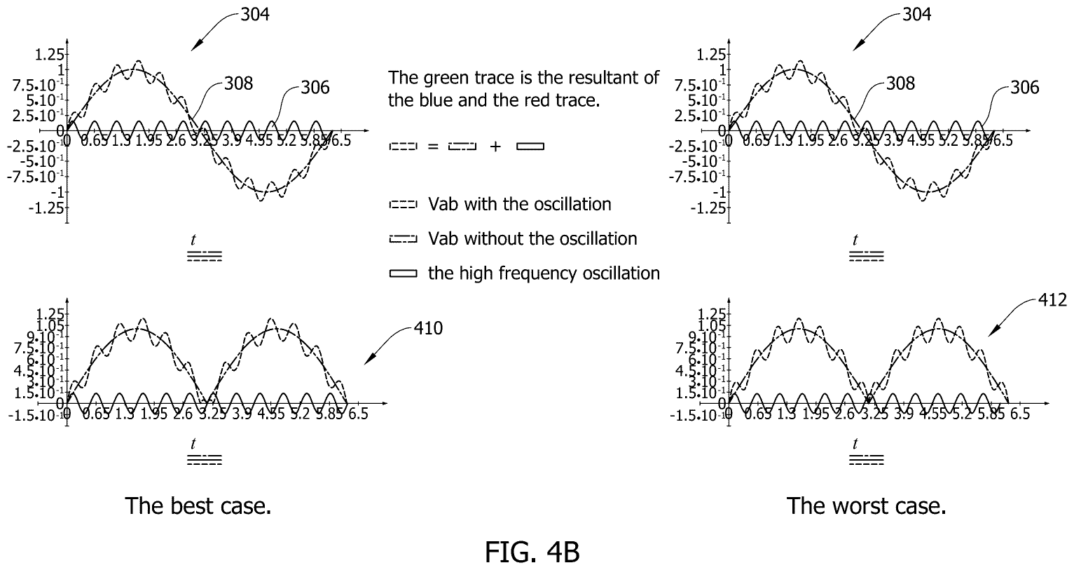

FIG. 4A show the cause of the high-frequency oscillation 306 in the secondary AC voltage V_{ab}. FIG. 4B shows the effects of the high-frequency oscillation 306 on the measurement of the secondary AC voltage V_{ab} when the mean value of the secondary AC voltage V_{ab} is used in measuring the mutual inductance M.

In the example embodiment, the circuit diagram 402-t of the system 100 may be simplified as circuit diagram 402-4m1 if the parasitic capacitance of the rectifier 128 is considered. The high-frequency oscillation 306 is caused by the parasitic capacitors (Csr_a or Csr_b) of the transistors 405 in the rectifier 128. The transistors 405 may be synchronous rectification field effect transistors. Csr_a denotes the capacitance of the parasitic capacitors of the transistors 405-a in phase leg a. Csr_b denotes the capacitance of the parasitic capacitors of the transistors 405-b in phase leg b. The circuit diagram 402 may be further simplified into circuit diagram 402-4m2, where Csr_ab denotes the capacitance of the series connected parasitic capacitors Csr_a and Csr_b.

In the example embodiment, because the capacitance of the parasitic capacitors is much smaller than the capacitance of the secondary compensation capacitor Cs, the circuit diagram 402-4m2 may be simplified as circuit diagram 402-4b, The frequency of the high-frequency oscillation 306 is approximately the resonant frequency of the resonant circuit 408 in the circuit diagram 402-b, which is determined by the inductance Ls of the receiver coil 126 and the capacitance Csr_ab of the parasitic capacitators 406 of the transistors 405.

Referring to FIG. 4B, in the example embodiment, when the period of the high-frequency oscillation 306 is a multiple of half of the period, or the semi-period, of the base component of the secondary AC voltage V_{ab}, the high-frequency oscillation 306 does not affect the mean of the secondary AC voltage V_{ab} (see plot 410). When the period of the high-frequency oscillation 306 is not a multiple of the semi-period of the base component of the secondary AC voltage V_{ab}, the high-frequency oscillation 306 affects the mean of the secondary AC voltage V_{ab} (see plot 412). The most severe case is when a period of the base component includes a multiple of the period and a semi-period of the high-frequency oscillation 306.

In operation, to minimize the effects of the high-frequency oscillation 306 on the measurement of the mutual inductance M, the operating frequency fs may be selected such that the period of the operating frequency is a multiple of a semi-period of the high-frequency oscillation 306. The frequency of the high-frequency oscillation 306 may be estimated as a resonant frequency of the resonant circuit 408 having an inductance Ls of the receiver coil 126 and parasitic capacitance of the parasitic capacitors 40 of the transistors 405.

Series-series compensation circuits are described herein as an example for illustration purposes only. The systems and methods described herein may be applied to the system 100 having other compensation circuits, such as parallel-series, parallel-parallel, series-parallel compensation circuits, or compensation circuits having composite topologies like LC-S, LCC-S, LC-LC, or LCC-LCC.

At least one technical effect of the systems and methods described herein includes (a) measuring mutual inductance in an IPT system before charging; (b) increased accuracy in measurement of mutual inductance using a ratio between the secondary AC voltage and the primary AC current of the IPT system when the IPT system is operated such that the secondary AC current is zero; (c) clamping the output DC voltage to a clamping voltage and operating the IPT system such that the secondary AC voltage is less than the clamping voltage, to meet the condition of zero secondary AC current at an operating frequency of the IPT system; (d) measuring the mean value or the peak value of the secondary AC voltage and the primary AC current in measuring mutual inductance; and (e) the operating frequency of the IPT system being not limited to the resonant frequency of the transmitter resonant circuit or the resonant frequency of the receiver resonant circuit.

Example embodiments of IPT systems and methods for operating the IPT systems are described above in detail. The systems and methods are not limited to the specific embodiments described herein but, rather, components of the systems and/or operations of the methods may be utilized independently and separately from other components and/or operations described herein. Further, the described components and/or operations may also be defined in, or used in combination with, other systems, methods, and/or devices, and are not limited to practice with only the systems described herein.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” and/or “substantially” as applied to a particular value of a range applies to both values, and unless otherwise dependent on the precision of the instrument measuring the value, may indicate+/−10% of the stated value(s).

As used herein, an element or step recited in the singular and proceeded with the word “a” or “an” should be understood as not excluding plural elements or steps, unless such exclusion is explicitly recited. Furthermore, references to “example” or “one example” of the present disclosure are not intended to be interpreted as excluding the existence of additional examples that also incorporate the recited features. Further, to the extent that terms “includes,” “including,” “has,” “contains,” and variants thereof are used herein, such terms are intended to be inclusive in a manner similar to the term “comprises” as an open transition word without precluding any additional or other elements.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A wireless inductive power transfer (IPT) system for wirelessly charging electrical equipment, the wireless IPT system comprising:
a transmitter resonant circuit configured to transmit a primary alternating current (AC) power, the primary AC power having a primary AC current;
a receiver resonant circuit inductively coupled with the transmitter resonant circuit and configured to receive the primary AC power and output a secondary AC power, the secondary AC power having a secondary AC voltage and a secondary AC current; and
a mutual inductance measurement circuitry configured, in order to measure a mutual inductance between the transmitter resonant circuit and the receiver resonant circuit before initiating charging of the electrical equipment, to:
operate the wireless IPT system such that the secondary AC current is zero at an operating frequency of the wireless IPT system;
measure the secondary AC voltage and the primary AC current;
determine the mutual inductance based on the secondary AC voltage and the primary AC current; and
output the determined mutual inductance.

2. The wireless IPT system of claim 1, further comprising:
an inverter configured to convert a direct current (DC) input power into the primary AC power; and
a rectifier configured to convert the secondary AC power into a DC output power,
wherein the mutual inductance measurement circuitry is further configured, to operate the wireless IPT system, to:
clamp a DC output voltage to a clamping voltage; and
adjust the input DC power such that the secondary AC voltage is less than the clamping voltage.

3. The wireless IPT system of claim 1, wherein the mutual inductance measurement circuitry is further configured to:
adjust operating parameters of the wireless IPT system during charging based on the determined mutual inductance.

4. The wireless IPT system of claim 1, wherein the mutual inductance measurement circuitry is configured to:
determine the mutual inductance based on a mean value of the secondary AC voltage and a mean value of the primary AC current.

5. The wireless IPT system of claim 1, wherein the mutual inductance measurement circuitry is configured to:
determine the mutual inductance based on a peak value or a mean value of the secondary AC voltage and a peak value or a mean value of the primary AC current.

6. The wireless IPT system of claim 1, further comprising an inverter configured to convert an input DC power to the primary AC power, wherein the mutual inductance measurement circuitry is further configured, to operate the wireless IPT system, to:
operate the inverter at an operating frequency different from a resonant frequency of the transmitter resonant circuit.

7. The wireless IPT system of claim 6, wherein the mutual inductance measurement circuitry is further configured, to operate the wireless IPT system, to:
operate the inverter at the operating frequency higher than the resonant frequency of the transmitter resonant circuit.

8. The wireless IPT system of claim 1, wherein the mutual inductance measurement circuitry is further configured to:
compare the determined mutual inductance with a predefined range; and
initiate charging of the electrical equipment if the determined mutual inductance is in the predefined range.

9. The wireless IPT system of claim 1, further comprising:
an inverter configured to convert an input DC power to the primary AC power; and
a rectifier configured to convert the secondary AC power into a DC output power,
wherein the mutual inductance measurement circuitry is further configured, to reduce effects on accuracy of the determined mutual inductance from a high-frequency oscillation in the secondary AC voltage, to:
operate the inverter at an operating frequency such that a semi-period of the operating frequency is a multiple of a period of the high-frequency oscillation, the high-frequency oscillation being caused by parasitic capacitors in the rectifier.

10. A mutual inductance measurement circuitry for measuring a mutual inductance in a wireless inductive power transfer (IPT) system before initiating charging of electrical equipment by the wireless IPT system, the wireless IPT system comprising a transmitter resonant circuit and a receiver resonant circuit inductively coupled with the transmitter resonant circuit, the transmitter resonant circuit configured to transmit a primary alternating current (AC) power having a primary AC current, the receiver resonant circuit configured to receive the primary AC power and output a secondary AC power, the secondary AC power having a secondary AC voltage and a secondary AC current, the mutual inductance measurement circuitry configured to:
operate the wireless IPT system such that the secondary AC current is zero at an operating frequency of the wireless IPT system;
measure the secondary AC voltage and the primary AC current;
determine the mutual inductance based on the secondary AC voltage and the primary AC current; and
output the determined mutual inductance.

11. The mutual inductance measurement circuitry of claim 10, wherein the mutual inductance measurement circuitry is further configured, to operate the wireless IPT system, to:
clamp a direct current (DC) output voltage of the wireless IPT system to a clamping voltage; and
adjust an input DC power of the wireless IPT system such that the secondary AC voltage is less than the clamping voltage.

12. A method of operating a wireless inductive power transfer (IPT) system for wirelessly charging electrical equipment, the wireless IPT system including a transmitter resonant circuit and a receiver resonant circuit inductively coupled with the transmitter resonant circuit, the transmitter resonant circuit configured to transmit a primary alternating current (AC) power having a primary AC current, the receiver resonant circuit configured to receive the primary AC power and output a secondary AC power, the secondary AC power having a secondary AC voltage and a secondary AC current, the method comprising:
before initiating charging of the electrical equipment by the wireless IPT system;
operating the wireless IPT system such that the secondary AC current is zero at an operating frequency of the wireless IPT system;
measuring the secondary AC voltage and the primary AC current;
determining a mutual inductance between the transmitter resonant circuit and the receiver resonant circuit based on the secondary AC voltage and the primary AC current; and
outputting the determined mutual inductance.

13. The method of claim 12, wherein operating the wireless IPT system further comprises:
clamping a direct current (DC) output voltage of the wireless IPT system to a clamping voltage; and
adjusting an input DC power of the wireless IPT system such that the secondary AC voltage is less than the clamping voltage.

14. The method of claim 12, further comprising:
adjusting operating parameters of the wireless IPT system during charging based on the determined mutual inductance.

15. The method of claim 12, wherein determining the mutual inductance further comprises:
determining the mutual inductance based on a mean value of the secondary AC voltage and a mean value of the primary AC current.

16. The method of claim 12, wherein determining the mutual inductance further comprises:
determining the mutual inductance based on a peak value or a mean value of the secondary AC voltage and a peak value or a mean value of the primary AC current.

17. The method of claim 12, wherein operating the wireless IPT system further comprises:
operating an inverter of the wireless IPT system at an operating frequency different from a resonant frequency of the transmitter resonant circuit.

18. The method of claim 17, wherein operating the wireless IPT system further comprises:
operating the inverter at the operating frequency higher than the resonant frequency of the transmitter resonant circuit.

19. The method of claim 12, further comprising:
comparing the determined mutual inductance with a predefined range; and
initiating charging of the electrical equipment if the determined mutual inductance is in the predefined range.

20. The method of claim 12, wherein operating the wireless IPT system further comprises:
reducing effects on accuracy of the determined mutual inductance from a high-frequency oscillation in the secondary AC voltage by:
operating an inverter of the wireless IPT system at an operating frequency such that a semi-period of the operating frequency is a multiple of a period of the high-frequency oscillation, the high-frequency oscillation being caused by parasitic capacitors in a rectifier of the wireless IPT system.
